(19) United States
(12) Patent Application Publication
(10) Pub. No.: US 2014/0070220 A1
(43) Pub. Date: Mar. 13, 2014

(54) ARRAY SUBSTRATE, METHOD FOR MANUFACTURING THE SAME AND DISPLAY DEVICE

(71) Applicant: BOE TECHNOLOGY GROUP CO., LTD., Beijing (CN)

(72) Inventors: Feng Zhang, Beijing (CN); Tianming Dia, Beijing (CN); Qi Yao, Beijing (CH)

(21) Appl. No.: 13/876,351

(22) PCT Filed: Dec. 7, 2012
(86) PCT No.: PCT/CN2012/086229

§ 371 Date: Mar. 27, 2013

(30) Foreign Application Priority Data
Feb. 27, 2012 (CN) 201210048574.7

(51) Int. Cl. H01L 21/288; H01L 29/786; H01L 29/66; H01L 29/45

(52) U.S. Cl. CPC H01L 21/288; H01L 29/45; H01L 29/786; H01L 29/66742
USPC 257/59; 257/72; 438/151

(57) ABSTRACT

Embodiments of the invention provide an array substrate, a method for manufacturing the same and a display device. The array substrate comprises a thin film transistor and a pixel electrode electrically connected to a drain electrode of the thin film transistor. The pixel electrode is formed of graphene, or a source electrode and the drain electrode of the thin film transistor are formed of graphene, or the pixel electrode, the source and drain electrodes of the thin film transistor are all formed of graphene.

### TECHNICAL FIELD

Embodiments of the invention relate to an array substrate, a method for manufacturing the array substrate and a display device.

### BACKGROUND

At present, an array substrate of a flat-panel display is generally formed by employing the following four patterning processes: (1) forming a gate electrode, (2) forming a gate insulating layer, an active layer, a source electrode and a drain electrode, (3) forming a passivation layer and a passivation layer through hole, and (4) forming a pixel electrode connected with the drain electrode through the passivation layer through hole. ITO (Indium Tin Oxide) is generally used to form the pixel electrode. But the following problems may be caused when ITO is employed: (1) ITO is expensive and thus it is difficult to reduce the manufacturing cost; (2) ion diffusions may easily occur when any of acids and alkalis exists around the ITO and thus it is harmful to environment of manufacture plants and human health; (3) performances of a component may degrade when ions diffuse into the component; (4) ITO is relatively brittle and thus it is easy to be damaged when it is deformed, and therefore it is difficult to be applied to flexible display field.

Graphene is a two-dimensional crystal formed of carbon atoms arrayed in a honeycomb-like shape. Graphene and its related devices have became a research focus in fields of physics, chemistry, biology and material science due to its quantum transport characteristic and high conductivity, mobility and transmittance.

At present, graphene may be obtained through many methods such as a mechanical stripping method, a chemical vapor deposition method, a method of thermal decomposition of SiC substrate and a chemical method. The mechanical stripping method is a method for preparing graphene by repeatedly attaching and peeling off a adhesive tap, by which sizes and number of layers of graphene films are difficult to be controlled and merely graphene films of about several millimeters magnitude may be obtained. The chemical vapor deposition method is a method of heating a carbon source such as methane and the like in a vacuum container to about 1000° C. so as to make it decompose and then forming a graphene film on a metal foil of such as Ni and Cu and the like. The method of thermal decomposition of SiC substrate is a method that Si atoms on a surface of the SiC substrate are removed after the SiC substrate is heated to about 1300° C. and the remaining C atoms spontaneously recombine with each other to form a graphene film. With the above manufacturing method, it is difficult to obtain a graphene film with a large area or a manufacturing temperature thereof is too high and thus a manufacturing cost is relatively high, which is disadvantage to be industrialization. The chemical method is a method that firstly oxidizing graphite powder and then dissolving the oxidized graphite powder into a solution, and thereafter coating a thin layer of the solution and reducing the solution. This method is simple, and has a relatively low temperature and relatively low cost, and thus may be used to manufacture a graphene film with a large area, and thus it is suitable for industrialization.

In graphene based-electron devices, a graphene film generally needs to be patterned, and the present processes for patterning the graphene film are as follows. (1) firstly patterning a catalyst layer, forming a graphene film on the patterned catalyst layer and then transferring the patterned graphene film to a substrate. Such method can not precisely position the patterned graphene onto the substrate. (2) firstly transferring a graphene film with a large area onto the substrate of the electronic device, and then obtaining a desired patterned graphene by a photolithography and an etching method. Such method employs an oxygen plasma etching process, which may inevitablely cause irradiation damage to the graphene film and other portions of the device. (3) utilizing a stamper to imprint the graphene film where the graphene is desired. Such method may require different stampers to form graphene films of different patterns, and a process for manufacturing a stamper is complicated and its cost is too high.

### SUMMARY OF THE INVENTION

According to an embodiment of the invention, an array substrate is provided. The array substrate comprises a thin film transistor and a pixel electrode electrically connected to a drain electrode of the thin film transistor. The pixel electrode is formed of graphene, or a source electrode and the drain electrode of the thin film transistor are formed of graphene, or the pixel electrode, the source and drain electrodes of the thin film transistor are all formed of graphene.

According to another embodiment of the invention, a method for manufacturing an array substrate is provided. The method comprises forming a thin film transistor and a pixel electrode electrically connected to a drain electrode of the thin film transistor. The pixel electrode is formed of graphene, or a source electrode and the drain electrode of the thin film transistor are formed of graphene, or the pixel electrode, the source and drain electrodes of the thin film transistor are all formed of graphene.

According to still another embodiment of the invention, a display device is provided. The display device comprises the above mentioned array substrate.

According to the embodiments of the invention, the pixel electrode is formed of graphene, or the source electrode and the drain electrode are formed of graphene, or the pixel electrode, the source electrode and the drain electrode are all formed of graphene. The graphene film has high chemical stability, few ion diffusions and few damages to the substrate, and thus is suitable to various substrates, for example the flexible substrate and so on. The cost can be greatly reduced and the competitive power of products can be increased when graphene films are employed. Meanwhile, the source electrode, the drain electrode and the pixel electrode are simultaneously formed by a same patterning process in the method for manufacturing the array substrate according to the embodiments of the invention, and thus manufacturing process can be simplified and the yield can be increased. In addition, when the oxidized graphene solution is employed to form the graphene film, the graphene film is patterned by simply forming the patterned photoresist or acrylic resin material on the substrate, and thus the patterned graphene film can be precisely provided on the substrate since the precisely patterned photoresist or acrylic resin material has been formed previously. The manufacturing process is easily implemented and does not need expensive equipments, and thus the cost can be reduced, and graphene films with large area can be formed and be used on a large scale.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic structural view of an array substrate according to an embodiment 1 of the invention, in which only one pixel region is illustrated as an example;

FIG. 2 is a sectional view taken along A-A′ in FIG. 1;

FIG. 3 is a schematic structural view after forming a gate electrode and a common electrode on a substrate according to an embodiment 4 of the invention;

FIG. 4 is a sectional view taken along A-A′ in FIG. 3;

FIG. 5 is a schematic structural view after forming a gate insulating layer, an active layer and an etch barrier layer on the substrate according to the embodiment 4 of the invention;

FIG. 6 is a sectional view taken along A-A′ in FIG. 5;

FIG. 7 is a sectional view after forming a patterned photoresist on the active layer, the etch barrier layer and the gate insulating layer according to the embodiment 4 of the invention;

FIG. 8 is a sectional view after forming a continuous graphene film layer on the patterned photoresist illustrated in FIG. 7; and

FIG. 9 is a sectional view of a resultant patterned graphene film.

### DESCRIPTION OF THE EMBODIMENTS

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

### Embodiment 1

An array substrate according to embodiments of the invention comprises a plurality of gate lines and a plurality of data lines. These gate lines and data lines cross with each other so as to define pixel regions arrayed in a matrix. Each pixel region comprises a thin film transistor and a pixel electrode. A gate electrode of the thin film transistor is formed to be electrically connected to or integrally formed with corresponding gate line, a source electrode is formed to be electrically connected to or integrally formed with corresponding data line, and a drain electrode is formed to be electrically connected to or integrally formed with corresponding pixel electrode.

The following descriptions are made mainly based on a single pixel region, but other pixel regions may be formed similarly.

For convenience of descriptions, embodiments of the invention are described based on the structure of the normal thin film transistor as an example, but embodiments of the invention are not limited thereto.

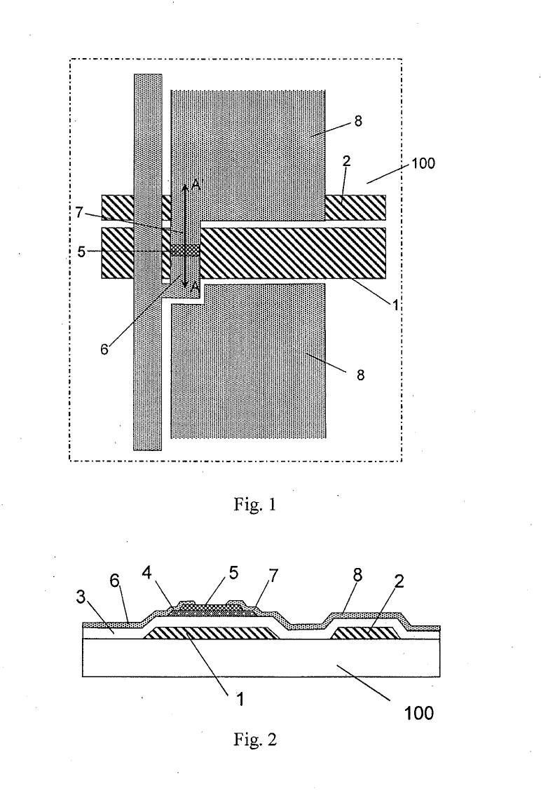

FIG. 1 is a schematic structural view of an array substrate according to the embodiment 1, in which only one pixel region is illustrated as an example. FIG. 2 is a sectional view taken along A-A′ in FIG. 1. As shown in FIG. 1 and 2, a thin film transistor and a pixel electrode are formed in the pixel region. A gate electrode 1 and a common electrode 2 are formed on a substrate 100. A gate insulating layer 3 is formed on the gate electrode 1 and the common electrode 2 to cover the gate electrode 1 and the common electrode 2. A semiconductor layer, that is, an active layer 4 is formed on the gate insulating layer 3 and above the gate electrode 1. An etch barrier layer 5 is formed on the active layer 4. A source electrode 6 continuously covers portions of the gate insulating layer 3, the active layer 4 and the etch barrier layer 5. A drain electrode 7 continuously covers portions of the etch barrier layer 5, the active layer 4 and the gate insulating layer 3. The source electrode 6 and the drain electrode 7 are opposite to and spaced apart from each other. A channel region is formed between the source electrode 6 and the drain electrode 7. The pixel electrode 8 is formed on the gate insulating layer 3, and the pixel electrode 8 and the drain electrode 7 are electrically connected to each other. The etch barrier layer 5 may be selectively provided according to practical manufacturing process. Preferably, the etch barrier layer 5 is provided to protect the active layer 4 from etching damages. Furthermore, optionally, the common electrode 2 may not be formed on the array substrate according to the present embodiment.

In order to increase the stability of the pixel electrode and wide the application range of the array substrate, the pixel electrode 8 is formed of graphene in the present embodiment. By utilizing graphene with excellent light transmittance, thermal conductivity and chemical stability, the chemical stability of the pixel electrode 8 can be improved, the manufacturing cost can be reduced, the array substrate can be applied to the flexible display field and thus the application range thereof can be widened.

In the present embodiment, the gate electrode 1 and the common electrode 2 may be formed of a same material. For example, Mo, Al, Cu, AlNd or their alloys (that is, Mo alloy, Al alloy, Cu alloy or AlNd alloy) may be used. Materials for the gate insulating layer 3 and the etch barrier layer 5 may be SiNx, SiO₂ and the like so as to provide corrosion-resistant property. The active layer 4 is a semiconductor layer, and may be formed of α-Si, α-IGZO and the like.

### Embodiment 2

A structure of an array substrate in the present embodiment is similar to that in the embodiment 1, and the differences therebetween are that the source electrode 6 and the drain electrode 7 in the present embodiment are formed of graphene. Since the source electrode 6 and the drain electrode 7 are formed in a same level by a same manufacturing process, the process of forming the source electrode 6 and the drain electrode 7 by graphene is simple. The source electrode 6 and the drain electrode 7 formed of graphene have high chemical stability, excellent flexibility, few ion diffusions and few damages to the substrate, therefore they can be applicable to various substrates such as flexible substrate and so on.

### Embodiment 3

A structure of an array substrate in the present embodiment is similar to that in the first embodiment, and the differences therebetween are that the source electrode 6 and the drain electrode 7 in the present embodiment are formed of graphene in addition to the pixel electrode 8. That is, all of the source electrode 6, the drain electrode 7 and the pixel electrode 8 are formed of graphene. Since the source electrode 6, the drain electrode 7 and the pixel electrode 8 are formed in a same level by a same manufacturing process and the drain. electrode 7 and the pixel electrode 8 are electrically connected to each other, the process for forming the source electrode 6, the drain electrode 7 and the pixel electrode 8 by graphene is simple and has low cost. In the present embodiment, the etch barrier layer 5 may be provided. The etch barrier layer 5 can protect the active layer 4 from being etched during forming the source electrode 6, the drain electrode 7 and the pixel electrode 8.

### Embodiment 4

The method for manufacturing an array substrate according to the present embodiment comprises two stages. A first stage comprises forming a gate electrode, a gate insulating layer and an active layer on a substrate by conventional processes. A common electrode and an etch barrier layer may also be formed in the first stage. A second stage comprises forming a source electrode, a drain electrode and/or a pixel electrode by graphene.

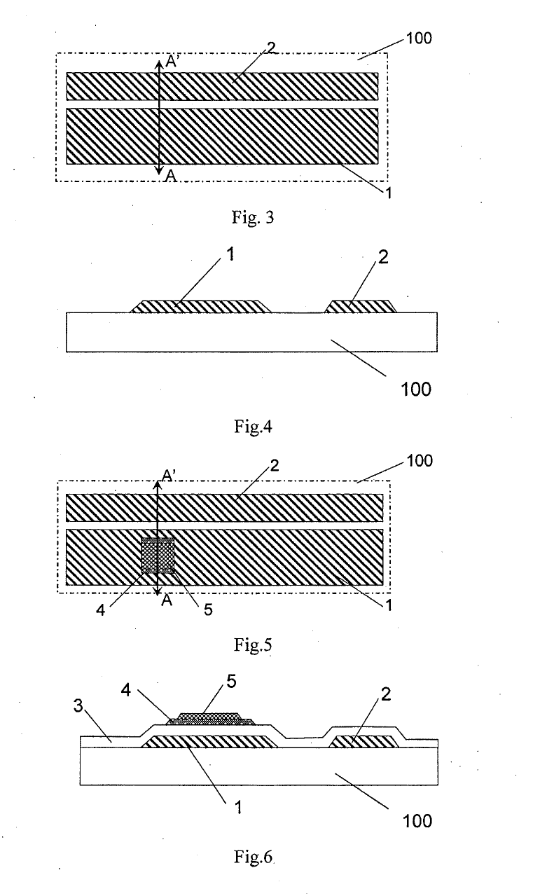

FIG. 3 to FIG. 6 illustrate the first stage which comprises the following steps.

Firstly, the gate electrode 1 is formed within each pixel region on the substrate 100. Alternatively, the common electrode 2 may be simultaneously formed.

The gate electrode 1 and the common electrode 2 are formed by depositing and patterning a metal film layer on the substrate 100, as shown in FIG. 3 and 4. The patterning process described in the present embodiment may be a conventional patterning process such as a photolithography process, a screen printing process, a printing process and so on and will not be described in detail hereinafter. For example, the above mentioned metal film may be formed of Mo, Al, Cu, AlNd or their alloys (that is, Mo alloy, Al alloy, Cu alloy or AlNd alloy).

Next, the gate insulating layer 3 and the active layer 4 are formed on the substrate 100 obtained by the aforesaid processes. Alternatively, the etch barrier layer 5 may be simultaneously formed.

The gate insulating layer 3, a semiconductor layer and an insulating layer are sequentially formed on the gate electrode 1 and the common electrode 2, and then the active layer 4 and the etch barrier layer 5 are formed on the gate insulating layer 3 above the gate electrode 1 by a patterning process, as shown in FIGS. 5 and 6. The gate insulating layer 3, the semiconductor layer and the insulating layer may be sequentially formed on the gate electrode 1 and the common electrode 2 by a depositing method, a coating method and so on, and details thereof will not be described hereinafter. Materials for forming the gate insulating layer 3 and the etch barrier layer 5 may be SiNx, SiO₂ and the like. The etch barrier layer 5 is used to protect the channel, and prevent the channel from being damaged and polluted in the subsequent etching process and other processes. The active layer 4 may be formed of α-Si, α-IGZO and the like.

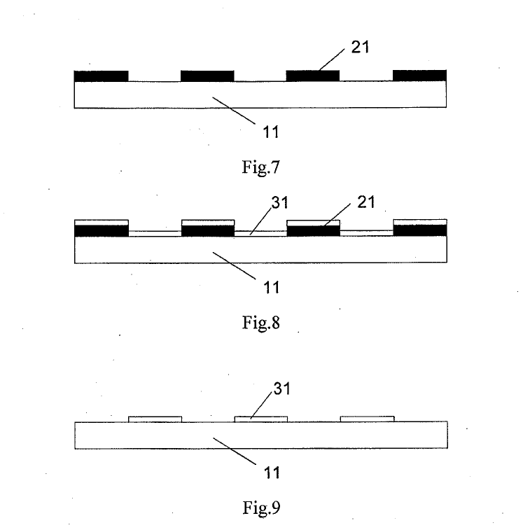

FIGS. 7-9 illustrate the second stage of the manufacturing method. During this manufacturing stage, the source electrode 6, the drain electrode 7 and the pixel electrode 8 are formed at a same level by graphene, and provided on the gate insulating layer 3, the active layer 4 and the etch barrier layer 5. For the convenience of description, the array substrate obtained by the first manufacturing stage is denoted as substrate 11 in FIGS. 7-9, and a patterning process for forming the source electrode 6, the drain electrode 7 and the pixel electrode 8 is described based on this substrate 11.

Firstly, a layer of photoresist 21 is formed on the substrate 11, and patterned so as to remove a portion of the photoresist 21 at regions where the source electrode 6, the drain electrode 7 and the pixel electrode 8 are to be formed.

For example, the photoresist 21 is patterned by a process such as an ultraviolet photolithography process or an electron-beam lithography process using a mask, wherein the portion of the photoresist 21 at the regions where the source electrode 6, the drain electrode 7 and the pixel electrode 8 are to be formed is removed by exposing and developing processes, as shown in FIG. 7.

Next, a layer of oxidized graphene solution is continuously formed on a surface of the substrate 11 so that the oxidized graphene solution continuously covers the photoresist 21 and the portion of the substrate 11 between patterns of the photoresist 21, and then the oxidized graphene solution is baked to form a layer of oxidized graphene film.

For example, the oxidized graphene solution is coated on the substrate 11 by a spin-coating method, a spray-coating method and so on. The solution is baked under 20˜80° C. at which the oxidized graphene film with compact and stable properties is formed quickly.

Next, the oxidized graphene film is reduced to obtain a layer of graphene film.

For example, the oxidized graphene film is reduced to the graphene film 31 by the steps of: placing the substrate 11 formed with the oxidized graphene film into an airtight container, heating an aqueous hydrazine solution to 60° C.-90° C. to generate a hydrazine steam and steaming the substrate 11 formed with the oxidized graphene film by the hydrazine steam for 24˜48 hours. By these steps, the graphene film 31 is obtained under optimal reducing conditions. The aqueous hydrazine solution for reducing the oxidized graphene as described above may be replaced with halide solutions such as hydriodic acid solution or hydrobromic acid solution.

Finally, the remaining portion of the photoresist 21 and the graphene film 31 formed thereon are removed by a photoresist stripping solution (such as acetone) so as to obtain the source electrode 6, the drain electrode 7 and the pixel electrode 8 formed of graphene.

For example, the substrate 11 is immersed into the photoresist stripping solution for 2 min-10 min so as to remove the photoresist 21 and the graphene film 31 formed thereon and to remain the graphene film 31 at the regions where the source electrode 6, the drain electrode 7 and the pixel electrode 8 are to be formed. In this way, the source electrode 6, the drain electrode 7 and the pixel electrode 8 are formed.

The oxidized graphene solution employed in the present embodiment may be available in the market. Moreover, a thickness of the photoresist 21 may be set to 1 μm-10 μm, which is larger than a thickness of the graphene film and ensures that the photoresist 21 and the graphene film 31 formed thereon are completely removed by the photoresist stripping solution. If the thickness of the photoresist 21 is too large, the photoresist is wasted. If the thickness of the photoresist 21 is too small, the graphene film entirely covers the patterned photoresist 21, the photoresist stripping solution does not directly contact the photoresist and thus the photoresist 21 and the graphene film 31 formed thereon are not completely removed.

In addition, the photoresist 21 in the present embodiment may be replaced with acrylic resin material, which produces a substantially same effect as that of the photoresist.

### Embodiment 5

A method for manufacturing an array substrate according to the present embodiment is similar to that in the embodiment 4, and the differences therebetween are that merely the pixel electrode 8 is formed of graphene. In this embodiment, the pixel electrode 8 of graphene may be formed by merely changing the mask structure employed in the patterning process of the photoresist 21 in the embodiment 4.

### Embodiment 6

A method for manufacturing an array substrate according to the present embodiment is similar to that in the embodiment 4, and the differences therebetween are that merely the source electrode 6 and the drain electrode 7 are formed of graphene. In this embodiment, the source electrode 6 and the drain electrode 7 of graphene may be formed by merely changing the mask structure employed in the patterning process of the photoresist 21 in the embodiment 4.

### Embodiment 7

The present embodiment provides a display device. The display device comprises the array substrate in the embodiment 1, 2 or 3.

In the present embodiment, the display device may be any products or components having display function such as a liquid crystal panel, an electronic paper, an OLED panel, a liquid crystal television, a liquid crystal display, a digital photo frame, a mobile telephone and a tablet PC and so on.

The electrodes in the embodiments of the invention are formed of graphene film, which is different from the conventional technology in which the pixel electrode is formed of ITO. The graphene film has high chemical stability, few ion diffusions and few damages to the substrate, and thus is suitable to various substrates, for example the flexible substrate and so on. The cost can be greatly reduced and the competitive power of products can be increased when graphene films are employed. Meanwhile, the source electrode, the drain electrode and the pixel electrode are simultaneously formed by a same patterning process in the method for manufacturing the array substrate according to the embodiments of the invention, and thus manufacturing process can be simplified and the yield can be increased. In addition, when the oxidized graphene solution is employed to form the graphene film, the graphene film is patterned by simply forming the patterned photoresist or acrylic resin material on the substrate, and thus the patterned graphene film can be precisely provided on the substrate since the precisely patterned photoresist or acrylic resin material has been formed previously. The manufacturing process is easily implemented and does not need expensive equipments, and thus the cost can be reduced, and graphene films with large area can be formed and be used on a large scale.

The foregoing descriptions are only exemplary embodiments of the invention, and are not used to define the protection scope of the invention. The protection scope of the invention is defined by the appended claims.

1. An array substrate comprising a thin film transistor and a pixel electrode electrically connected to a drain electrode of the thin film transistor, wherein the pixel electrode is formed of graphene, or a source electrode and the drain electrode of the thin film transistor are formed of graphene, or the pixel electrode, the source and drain electrodes of the thin film transistor are all formed of graphene.

2. The array substrate according to claim 1, wherein an etch barrier layer is formed on an active layer of the thin film transistor.

3. A method for forming an array substrate comprising forming a thin film transistor and a pixel electrode electrically connected to a drain electrode of the thin film transistor, wherein the pixel electrode is formed of graphene, or a source electrode and the drain electrode of the thin film transistor are formed of graphene, or the pixel electrode, the source and drain electrodes of the thin film transistor are all formed of graphene.

4. The method for forming the array substrate according to claim 3, wherein the pixel electrode is formed of graphene by following steps:
S1, forming a layer of photoresist on a substrate, and performing a patterning process on the photoresist to remove the photoresist at a region where the pixel electrode is to be formed;
S2, forming a layer of oxidized graphene solution on the substrate obtained by the step S1, and baking the oxidized graphene solution to form a layer of oxidized graphene film;
S3, reducing the oxidized graphene film to form a layer of graphene film;
S4, removing a remaining portion of the photoresist and the graphene film formed thereon to obtain the pixel electrode formed of the graphene film.

5. The method for forming the array substrate according to claim 3, wherein the source and drain electrodes are formed of graphene by following steps:
S21, forming a layer of photoresist on a substrate, and performing a patterning process on the photoresist to remove the photoresist at regions where the source and drain electrodes are to be formed;
S22, forming an oxidized graphene solution on the substrate obtained by the step S21, and baking the oxidized graphene solution to form a layer of oxidized graphene film;
S23, reducing the oxidized graphene film to form a layer of graphene film;
S24, removing a remaining portion of the photoresist and the graphene film formed thereon to obtain the source and drain electrodes formed of the graphene film.

6. The method for forming the array substrate according to claim 3, wherein the source electrode, the drain electrode and the pixel electrode are all formed of graphene by following steps:
S31, forming a layer of photoresist on a substrate, and performing a patterning process on the photoresist to remove the photoresist at regions where the source electrode, the drain electrode and the pixel electrode are to be formed;
S32, forming an oxidized graphene solution on the substrate obtained by the step S31, and baking the oxidized graphene solution to form a layer of oxidized graphene film;
S33, reducing the oxidized graphene film to form a layer of graphene film;
S34, removing a remaining portion of the photoresist and the graphene film formed thereon to obtain the source electrode, the drain electrode and the pixel electrode formed of the graphene film.

7. The method for forming the array substrate according to claim 4, wherein the oxidized graphene solution is baked to form the oxidized graphene film under 20˜80° C. and the oxidized graphene film is reduced by using an aqueous hydrazine solution.

8. (canceled)

9. The method for forming the array substrate according to claim 7, wherein reducing the oxidized graphene film to form a graphene film comprises: heating the aqueous hydrazine solution to 60° C.-90° C. in an airtight container to generate a hydrazine steam, and steaming the oxidized graphene film by the hydrazine steam for 24˜48 hours so as to obtain the graphene film by reducing.

10. A display device comprising the array substrate according to claim 1.

11. The method for forming the array substrate according to claim 5, wherein the oxidized graphene solution is baked to form the oxidized graphene film under 20° C.˜80° C. and the oxidized graphene film is reduced by using an aqueous hydrazine solution.

12. The method for forming the array substrate according to claim 11, wherein reducing the oxidized graphene film to form a graphene film comprises: heating the aqueous hydrazine solution to 60° C.-90° C. in an airtight container to generate a hydrazine steam, and steaming the oxidized graphene film by the hydrazine steam for 24˜48 hours so as to obtain the graphene film by reducing.

13. The method for forming the array substrate according to claim 6, wherein the oxidized graphene solution is baked to form the oxidized graphene film under 20° C.-80° C. and the oxidized graphene film is reduced by using an aqueous hydrazine solution.

14. The method for forming the array substrate according to claim 13, wherein reducing the oxidized graphene film to form a graphene film comprises: heating the aqueous hydrazine solution to 60° C.-90° C. in an airtight container to generate a hydrazine steam, and steaming the oxidized graphene film by the hydrazine steam for 24˜48 hours so as to obtain the graphene film by reducing.
